(19) United States
(12) Patent Application Publication
(10) Pub. No.: US 2026/0214979 A1
(43) Pub. Date: Jul. 23, 2026

(54) SEMICONDUCTOR DEVICE AND METHOD FOR FORMING THE SAME

(71) Applicant: TAIWAN SEMICONDUCTOR MANUFACTURING COMPANY, LTD., Hsinchu (TW)

(72) Inventors: Ting-Hsuan LAI, New Taipei City (TW); Hao-Chin HUANG, Kaohsiung City (TW); Wei-Yip LOH, Hsinchu City (TW)

(73) Assignee: TAIWAN SEMICONDUCTOR MANUFACTURING COMPANY, LTD., Hsinchu (TW)

(21) Appl. No.: 19/033,648

(22) Filed: Jan. 22, 2025

(51) Int. Cl. H10D 84/85; H10D 30/00; H10D 30/01; H10D 62/10; H10D 62/13; H10D 64/01; H10D 84/01

(52) U.S. Cl. CPC H10D 84/851; H10D 30/0191; H10D 30/502; H10D 62/121; H10D 62/151; H10D 84/017; H10D 84/0186; H10D 84/856; H10D 64/017

(57) ABSTRACT

A semiconductor device includes a substrate. A bottom device is over the substrate comprises a bottom source/drain structure. A top device is vertically above the bottom device and comprises a top source/drain structure. A first metal plug is vertically between the bottom source/drain structure and the top source/drain structure, in which a top surface of the first metal plug is lower than a top surface of the top source/drain structure.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. However, since feature sizes continue to decrease, fabrication processes continue to become more difficult to perform. Therefore, it is a challenge to form reliable semiconductor devices at smaller and smaller sizes.

As the semiconductor industry further progresses into technology process nodes in pursuit of higher device density, higher performance, and lower costs, challenges from both fabrication and design issues have led to stacked device structure configurations, such as complementary field effect transistors (C-FET) where an n-type multi-gate transistor and a p-type multi-gate transistor are stacked vertically, one over the other. While existing C-FET structures are generally adequate, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of a semiconductor device in accordance with some embodiments of the present disclosure.

FIGS. 2A to 18B illustrate a method in various stages of forming a semiconductor device in accordance with some embodiments of the present disclosure.

FIGS. 19A to 24B illustrate a method in various stages of forming a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

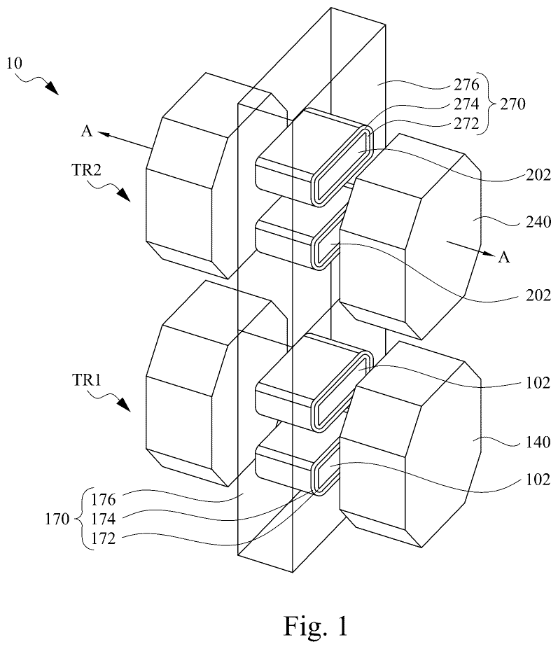

FIG. 1 is a perspective view of a semiconductor device in accordance with some embodiments of the present disclosure. In the present disclosure, a complementary FET (CFET) 10 is provided, and its manufacturing method will be disclosed in the following discussion. In a CFET 10, first transistors TR1 are disposed over a substrate (not shown), and second transistors TR2 are disposed vertically above the respective first transistors TR1. In some embodiments, the first transistors TR1 and the second transistors TR2 each may be field effect transistor (FET) and may both include gate-all-around (GAA) configuration, and thus the first transistors TR1 and the second transistors TR2 can also be referred to as GAA FETs. Each of the first transistors TR1 includes first semiconductor channel layers 102 vertically stacked one above another, a first metal gate structure 170 wrapping around each of the first semiconductor channel layers 102, and first source/drain epitaxy structures 140 on opposite ends of each of the first semiconductor channel layers 102. Similarly, each of the second transistors TR2 includes second semiconductor channel layers 202 vertically stacked one above another, a second metal gate structure 270 wrapping around each of the second semiconductor channel layers 202, and second source/drain epitaxy structures 240 on opposite ends of each of the second semiconductor channel layers 202. The first metal gate structure 170 may include an interfacial layer 172, a gate dielectric layer 174, and a gate electrode 176. Similarly, the second metal gate structure 270 may include an interfacial layer 272, a gate dielectric layer 274, and a gate electrode 276. In some embodiments, each of the first transistors TR1 has a first conductivity type (e.g., p-type) and each of the second transistors TR2 has a second conductivity type (e.g., n-type) different from the first conductivity type. In some embodiments, the first transistors TR1 can be referred to as P-FETs, and the second transistors TR2 can be referred to as N-FETs.

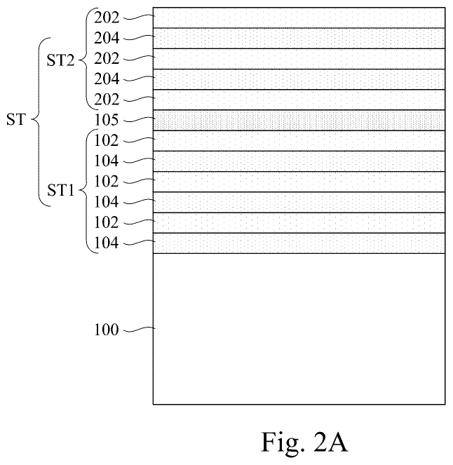

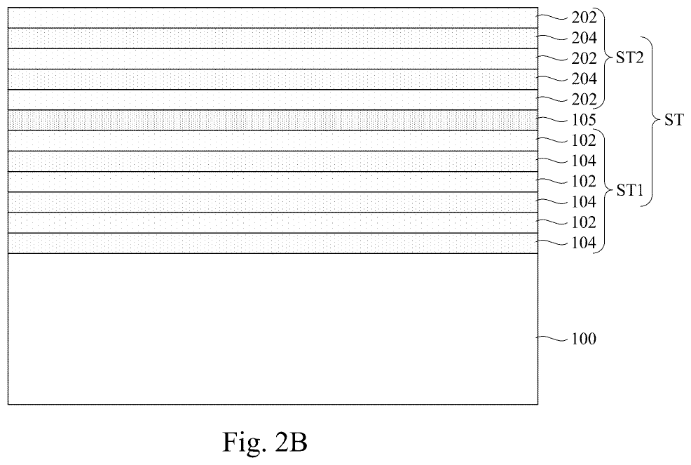

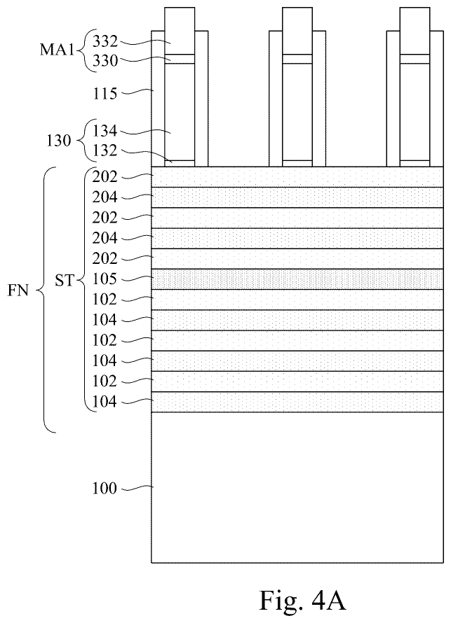

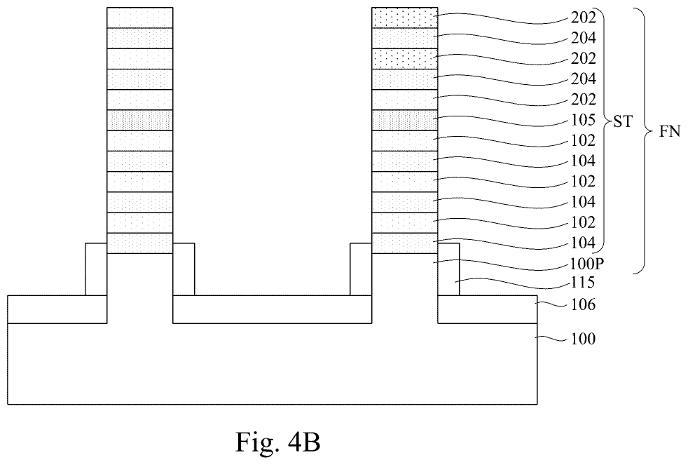

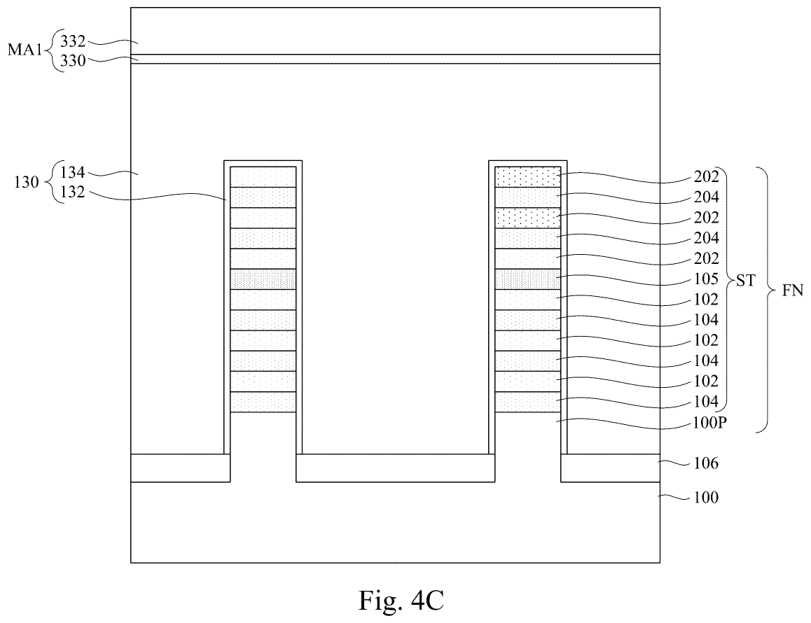

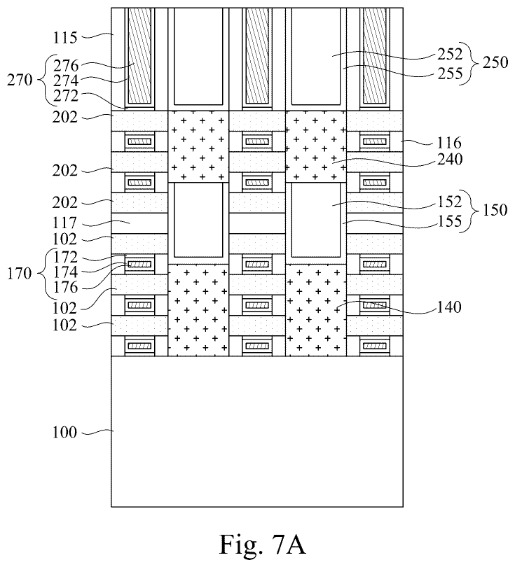

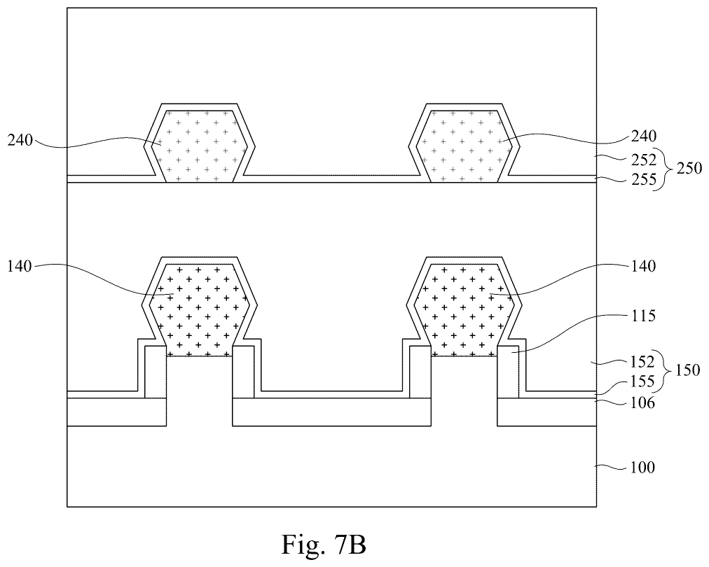

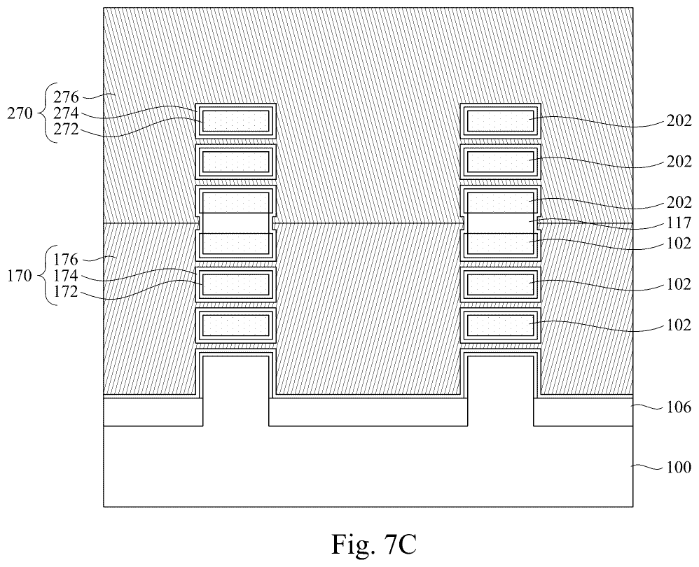

FIGS. 2A to 18B illustrate a method in various stages of forming a semiconductor device in accordance with some embodiments of the present disclosure. It is noted that FIGS. 2A, 3A, 4A, 5A, 6A, 7A, 8A, 9A, 10A, 11A, 12A, 13A, 14A, 15A, 16A, 17A, and 18A include cross-sectional views the same as the cross-sectional view along line A-A of FIG. 1. FIGS. 2B, 3B, 4B, 5B, 6B, 7B, 8B, 9B, 10B, 11B, 12B, 13B, 14B, 15B, 16B, 17B, and 18B include cross-sectional views the same as the cross-sectional view along line B-B of FIG. 1. FIGS. 4C, 7C, include cross-sectional views the same as the cross-sectional view along line C-C of FIG. 1. Although FIGS. 2A to 18B are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part. It is noted that some elements of FIGS. 2A to 18B may be similar to those described with respect to FIG. 1, and thus relevant details will not be repeated for brevity.

Reference is made to FIGS. 2A and 2B. Shown there is a substrate 100. Generally, the substrate 100 may include a bulk semiconductor substrate or a silicon-on-insulator (SOI) substrate. An SOI substrate includes an insulator layer below a thin semiconductor layer that is the active layer of the SOI substrate. The semiconductor of the active layer and the bulk semiconductor generally include the crystalline semiconductor material silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), oxide semiconductors (e.g., ZnO, SnO₂, TiO₂, Ga₂O₃, and the like) or combinations thereof. The semiconductor materials may be doped or undoped. Other substrates that may be used include multi-layered substrates, gradient substrates, or hybrid orientation substrates.

A semiconductor stack ST is formed over the substrate 100. The semiconductor stack ST includes a first stack ST1 of alternating semiconductor layers 102 and 104, a semiconductor layer 105 disposed over the first stack ST1, and a second stack ST2 of alternating semiconductor layers 202 and 204 over the semiconductor layer 105. In some embodiments, the semiconductor layers 102 and 202 may be made of pure silicon layers that are free of germanium. The semiconductor layers 102 and 202 may also be substantially pure silicon layers, for example, with a germanium percentage lower than about 1 percent. The semiconductor layers 104, 105, and 204 may be made of silicon germanium, while the semiconductor layer 105 may include a higher germanium composition than the semiconductor layers 104 and 204. For example, the germanium percentage (atomic percentage concentration) of the semiconductor layer 105 is in a range from about 60 percent and about 80 percent, and the germanium percentage (atomic percentage concentration) of the semiconductor layers 104 and 204 is in a range from about 20 percent and about 40 percent. In some embodiments, the semiconductor layers 102, 104, 105, 202, and 204 may be deposited using suitable deposition process, such as selective epitaxial growth (SEG), chemical vapor deposition (CVD), molecular beam epitaxy (MBE), or other suitable process(es). In some embodiments, the semiconductor layers 104 and 204 may be removed during a replacement gate (RPG) process, and thus the semiconductor layers 104 and 204 can also be referred to as sacrificial layers.

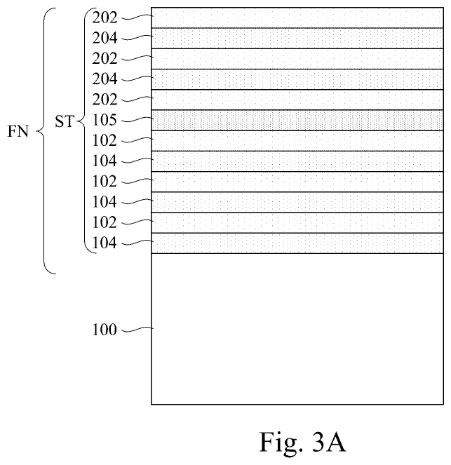

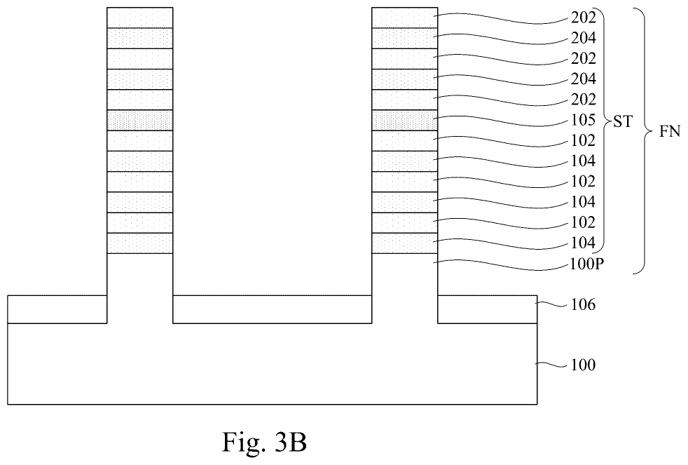

Reference is made to FIGS. 3A and 3B. A patterning process is performed to the semiconductor stack ST and the substrate 100 to form fin structures FN. In some embodiments, the patterning process may include forming a patterned photoresist layer over the stack ST, and then performing an etching process to remove unwanted portions of the semiconductor stack ST and the substrate 100 exposed by the patterned photoresist layer. Each of the fin structures FN may include a remaining portion of the semiconductor stack ST and a semiconductor strip 100P protruding over the substrate 100. In some embodiments, the etching process may include wet etch, dry etch, or the like.

After the fin structures FN are formed, isolation structures 106 are formed over the substrate 100 and laterally surrounding the fin structures FN. In some embodiments, the isolation structures 106 may be in contact with sidewalls of the semiconductor strip 100P of the substrate 100. The isolation structures 106 may be shallow trench isolation (STI) structures, suitable isolation structures, combinations of the foregoing, or the like. In some embodiments, the isolation structures 106 may be made of oxide (e.g., silicon oxide), nitride (e.g., silicon nitride), or combinations thereof.

Reference is made to FIGS. 4A, 4B, and 4C. Dummy gate structures 130 are formed over the substrate 100 and crossing the fin structures FN (see FIG. 4C). In some embodiments, each of the dummy gate structures 130 includes a dummy gate dielectric 132 and a dummy gate electrode 134 over the dummy gate dielectric 132. The dummy gate dielectric 132 may be, for example, silicon oxide, silicon nitride, a combination thereof, or the like, and may be deposited or thermally grown according to acceptable techniques. The dummy gate electrode 134 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals.

The dummy gate electrode 134 and the dummy gate dielectric 132 may be formed by, for example, depositing a dummy dielectric layer and a dummy gate layer over the substrate 100, forming patterned masks MA1 over the dummy gate layer, and then performing an etching process to the dummy dielectric layer and the dummy gate layer by using the patterned masks MA1 as etch mask. In some embodiments, the dummy gate electrode 134 may be deposited by physical vapor deposition (PVD), chemical vapor deposition (CVD), sputter deposition, or other techniques for depositing the selected material. In some embodiments, the dummy gate dielectric 132 may be formed by thermal oxidation.

In some embodiments, each of the patterned masks MA1 includes a first hard mask 330 and a second hard mask 332 over the first hard mask 330. The first hard mask 330 and the second hard mask 332 may be made of different materials. In some embodiments, the first hard mask 330 may be formed of silicon nitride, and the second hard mask 332 may be formed of silicon oxide.

Spacers 115 are formed on opposite sidewalls of each of the dummy gate structures 130 (see FIG. 4A), and on opposite sidewalls of the fin structures FN (see FIG. 4B). In some embodiments, portions of the spacers 115 on opposite sidewalls of each of the dummy gate structures 130 can be referred to as gate spacers, and portions of the spacers 115 on opposite sidewalls of the fin structures FN can be referred to as fin spacers. In some embodiments, the spacers 115 may be formed of silicon oxide, silicon nitride, silicon oxynitride, combinations thereof. In some embodiments, the spacers 115 may be formed by, for example, depositing a spacer layer blanket over the substrate, and then performing an anisotropic etching process to remove horizontal portions of the spacer layer, such that vertical portions of the spacer layer remain on sidewalls of the dummy gate structures 130 and on sidewalls of the fin structures FN. In some embodiments, the remaining vertical portions of the spacer layer can be referred to as the spacers 115. The spacer layer may be deposited using techniques such CVD, ALD, or the like.

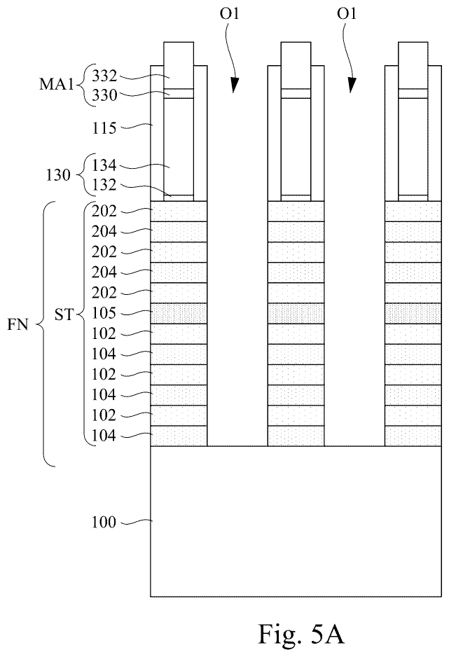

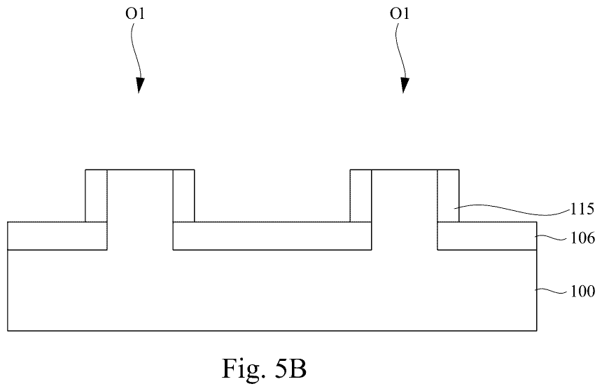

Reference is made to FIGS. 5A and 5B. An etching process is performed to remove portions of the fin structures FN (or the stacks ST) by using the dummy gate structures 130 and the spacers 115 as etch mask, so as to form source/drain openings O1 in the fin structures FN (or in the stacks ST). In some embodiments, the etching process may be wet etch, dry etch, or combinations thereof. In some embodiments, the bottommost ends of the source/drain openings O1 may be lower than the bottommost semiconductor layer 104.

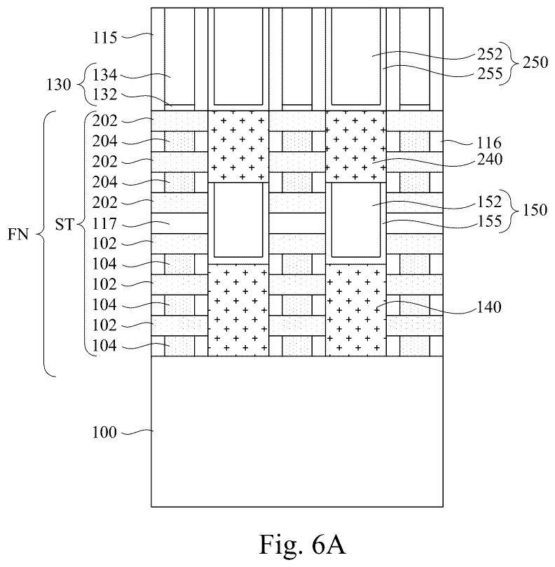

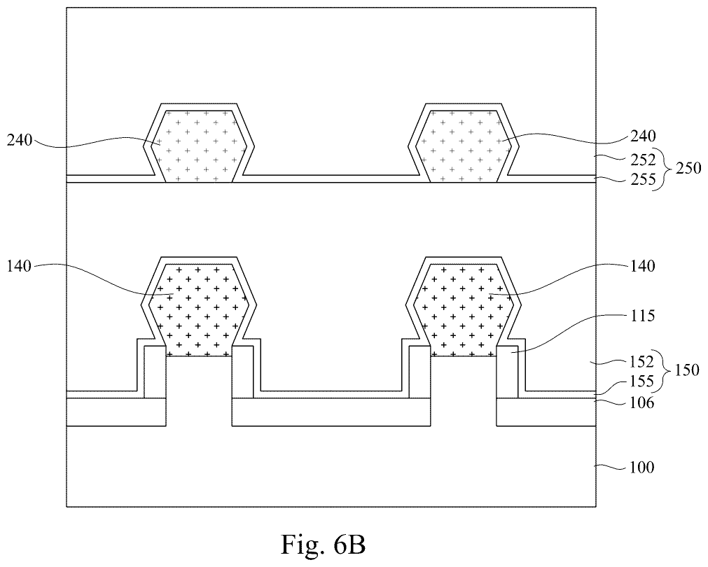

Reference is made to FIGS. 6A and 6B. Inner spacers 116 and dielectric isolation layers 117 are formed. Forming inner spacers 116 and dielectric isolation layers 117 may include an etching process that laterally etches the semiconductor layers 104 and 204 and removes the semiconductor layers 105. The etching process may be isotropic and may be selective to the material of the semiconductor layers 104, 105, and 204, so that the semiconductor layers 104, 105, and 204 are etched at a faster rate than the semiconductor layers 102 and 202. The etching process may also be selective to the material of the semiconductor layers 105, so that the semiconductor layers 105 are etched at a faster rate than the semiconductor layers 104 and 204. In this manner, the semiconductor layers 105 may be completely removed, while the semiconductor layers 104 and 204 are laterally shortened. In some embodiments where the semiconductor layers 105 are formed of germanium or silicon germanium with a higher germanium atomic percentage than the semiconductor layers 104 and 204, the semiconductor layers 104 and 204 are formed of silicon germanium with a lower germanium atomic percentage than the semiconductor layers 105, and the semiconductor layers 102 and 202 are formed of silicon free from germanium, the etch process may comprise a dry etch process using chlorine-containing gas, with or without a plasma.

Inner spacers 116 are formed on sidewalls of the recessed semiconductor layers 104 and 204, and dielectric isolation layers 117 are formed between the topmost semiconductor layer 102 and the bottommost semiconductor layer 104. As subsequently described in greater detail, source/drain structures will be subsequently formed in the source/drain openings O1, and the semiconductor layers 104 and 204 will be replaced with corresponding gate structures. The inner spacers 116 act as isolation features between the subsequently formed source/drain structures and the subsequently formed gate structures. Further, the inner spacers 116 may be used to prevent damage to the subsequently formed source/drain structures by subsequent etch processes, such as the etch processes used to form gate structures. Dielectric isolation layers 117, on the other hand, are used to isolate the upper semiconductor layers 104 from the lower semiconductor layers 102.

The inner spacers 116 and the dielectric isolation layers 117 may be formed by conformally depositing an insulating material in the source/drain openings O1, on sidewalls of the semiconductor layers 104 and 204, and in the gap between the topmost semiconductor layer 102 and the bottommost semiconductor layer 104, and then etching the insulating material. The insulating material may be a non-low-k dielectric material, which may be a carbon-containing dielectric material such as silicon oxycarbonitride, silicon oxycarbide, or the like. The insulating material may be formed by a deposition process, such as ALD, CVD, or the like. The etching of the insulating material may be anisotropic or isotropic. The insulating material, when etched, has portions remaining in the sidewalls of the semiconductor layers 104 and 204 (thus forming the inner spacers 116) and has portions remaining in the gap between the topmost semiconductor layer 102 and the bottommost semiconductor layer 104 (thus forming the dielectric isolation layers 117). As a result, the inner spacers 116 and the dielectric isolation layers 117 may be made of the same dielectric material.

First source/drain epitaxy structures 140 are formed in the openings O1, respectively. The first source/drain epitaxy structures 140 may be formed by suitable deposition process, such as a selective epitaxial growth (SEG) process. In some embodiments, the SEG process may selectively grow a semiconductor material on exposed semiconductor surfaces, such as the exposed surfaces of the substrate 100 and the exposed surfaces of the semiconductor layers 102. In some embodiments, an implantation process may be performed to the first source/drain epitaxy structures 140. For example, the implantation process may include p-type dopants, such as boron (B), gallium (Ga), indium (In), aluminium (Al), or the like, such that the first source/drain epitaxy structures 140 are p-type epitaxy structures. In some embodiments where the first source/drain epitaxy structures 140 are p-type epitaxy structures, the first source/drain epitaxy structures 140 may be made of silicon germanium (SiGe) or silicon (Si).

A contact etch stop layer (CESL) 155 is formed covering the first source/drain epitaxy structures 140. Afterwards, an interlayer dielectric (ILD) layer 152 is formed over the CESL 155. Then, an etching back process is performed to lower top surfaces of the CESL 155 and the ILD layer 152, such that sidewalls of the semiconductor layers 202 are exposed through the source/drain openings O1. In some embodiments, the CESL 155 and the ILD layer 152 can be collectively referred to as an isolation structure 150. In some embodiments, the topmost semiconductor layer 102 and the bottommost semiconductor layer 202 are in contact with the CESL 155 of the isolation structure 150.

In some embodiments, the CESL 155 may be nitride (such as silicon nitride), and the ILD layer 152 may be oxide (such as silicon oxide). In some embodiments, the CESL 155 may be a dielectric layer including silicon nitride, silicon oxynitride or other suitable materials. In some embodiments, the ILD layer 152 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The CESL 155 and the ILD layer 152 can be formed using, for example, CVD, ALD or other suitable techniques.

Second source/drain epitaxy structures 240 are formed on opposite ends of each o the semiconductor layers 202. In some embodiments, the second source/drain epitaxy structures 240 may be formed by a selective epitaxial growth (SEG) process. The SEG process may selectively grow a semiconductor material on exposed semiconductor surfaces, such as the exposed surfaces of the semiconductor layers 202. In some embodiments, an implantation process may be performed to the second source/drain epitaxy structures 240. For example, the implantation process may include n-type dopants, such as phosphorus (P), arsenic (As), or antimony (Sb), or the like, such that the second source/drain epitaxy structures 240 are n-type epitaxy structures. In some embodiments where the second source/drain epitaxy structures 240 are n-type epitaxy structures, the second source/drain epitaxy structures 240 may be made of silicon (Si).

A contact etch stop layer (CESL) 255 is formed covering the second source/drain epitaxy structures 240. Afterwards, an interlayer dielectric (ILD) layer 252 is formed over the CESL 255. Then, a planarization process, such as CMP, is performed to remove excess materials of the CESL 255 and the ILD layer 252 until the dummy gate structures 130 are exposed. In some embodiments, the patterned masks MA1 are removed during the planarization process. In some embodiments, the CESL 255 and the ILD layer 252 can be collectively referred to as an isolation structure 250. The materials of the CESL 255 and the ILD layer 252 may be similar to the materials of the CESL 155 and the ILD layer 152, respectively. For example, the CESL 255 may be nitride (such as silicon nitride), and the ILD layer 252 may be oxide (such as silicon oxide).

Reference is made to FIGS. 7A, 7B, and 7C. The dummy gate structures 130 are removed to form gate trenches between each pair of the gate spacers 115. Then, an etching process is performed to remove the semiconductor layers 104 and 204 through the gate trenches, such that the semiconductor layers 102 and 202 are suspended over the substrate 100 (see FIG. 7C).

Interfacial layers 172 and 272 are formed on exposed surfaces of the semiconductor layers 102 and 202, respectively. Then, gate dielectric layers 174 and 274 are formed over the interfacial layers 172 and 272, respectively. In some embodiments, the interfacial layers 172 and 272 may be formed using a same deposition process, and the gate dielectric layers 174 and 274 may be formed using a same deposition process.

After the interfacial layers 172 and 272 and the gate dielectric layers 174 and 274 are formed, gate electrodes 176 are formed in the gate trenches and over the gate dielectric layers 174. The gate electrodes 176 are then etched back, such that the remaining gate electrodes 176 are at the lower portion of the gate trenches. Accordingly, first metal gate structures 170 are formed. In greater detail, the first metal gate structures 170 are formed in bottom portions of the gate trenches, such that the first metal gate structures 170 may wrap around the respective semiconductor layers 102. In some embodiments, each of the first metal gate structures 170 may include the interfacial layer 172, the gate dielectric layer 174 over the interfacial layer 172, and the gate electrode 176 over the gate dielectric layer 174.

In some embodiments, the interfacial layers 172 and 272 may be made of oxide, such as aluminum oxide (Al₂O₃), silicon oxide (SiO₂), or the like. In some embodiments, the gate dielectric layers 174 and 274 may include high-k dielectric. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof.

The gate electrodes 176 may include work function metal layer(s) and a filling metal. The work function metal layer may be an n-type or p-type work function layer. Exemplary p-type work function metals include TiN, TaN, Ru, Mo, Al, WN, ZrSi₂, MoSi₂, TR1 asi₂, NiSi₂, WN, other suitable p-type work function materials, or combinations thereof. Exemplary n-type work function metals include Ti, Ag, TaAl, TaAlC, TiAlN, TaC, TaCN, TR1 asiN, Mn, Zr, other suitable n-type work function materials, or combinations thereof. The work function layer may include a plurality of layers. The filling metal may include tungsten (W), aluminum (Al), copper (Cu), or another suitable conductive material(s).

Gate electrodes 276 are formed in the gate trenches and over the first metal gate structures 170. Accordingly, second metal gate structures 270 are formed. In greater detail, the second metal gate structures 270 are formed in upper portions of the gate trenches and above the first metal gate structures 170, such that the second metal gate structures 270 may wrap around the respective semiconductor layers 202. In some embodiments, each of the second metal gate structures 270 may include the interfacial layer 272, the gate dielectric layer 274 over the interfacial layer 272, and the gate electrode 276 over the gate dielectric layer 274. The materials of the gate electrode 276 may be similar to those described with respect to the gate electrode 176, and thus relevant details will not be repeated for brevity.

The first metal gate structure 170, the first source/drain epitaxy structures 140 on opposite sides of the first metal gate structure 170, and the semiconductor layers 102 that are in contact with the first source/drain epitaxy structures 140 may collectively serve as the first transistor TR1 as described in FIG. 1. In such condition, the semiconductor layers 102 that are in contact with the first source/drain epitaxy structures 140 may also be referred to as channel layers of the first transistor TR1. Similarly, the second metal gate structure 270, the second source/drain epitaxy structures 240 on opposite sides of the second metal gate structure 270, and the semiconductor layers 202 that are in contact with the second source/drain epitaxy structures 240 may collectively serve as the second transistor TR2 as described in FIG. 1. In such condition, the semiconductor layers 202 that are in contact with the second source/drain epitaxy structures 240 may also be referred to as channel layers of the second transistor TR2. In FIG. 7A, opposite ends of the topmost semiconductor layer 102 are in contact with the isolation structures 150, and are not in contact with the first source/drain epitaxy structures 140. Thus, the topmost semiconductor layer 102 may not function as a channel layer of the first transistor TR1. Similarly, opposite ends of the bottommost semiconductor layer 202 are in contact with the isolation structure 150, and are not in contact with the second source/drain epitaxy structures 240. Thus, the topmost bottommost semiconductor layer 202 may not function as a channel layer of the second transistor TR2.

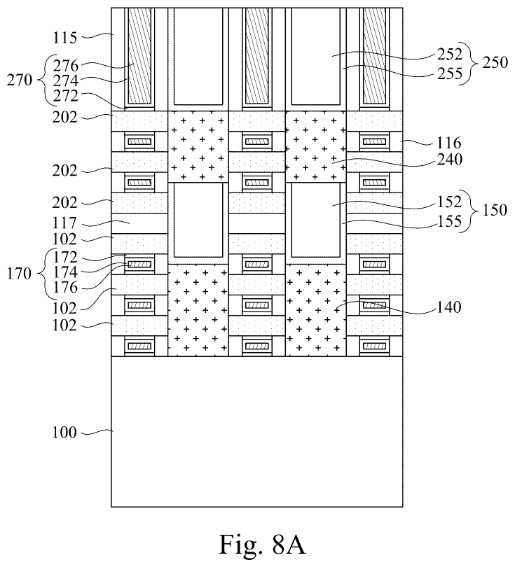

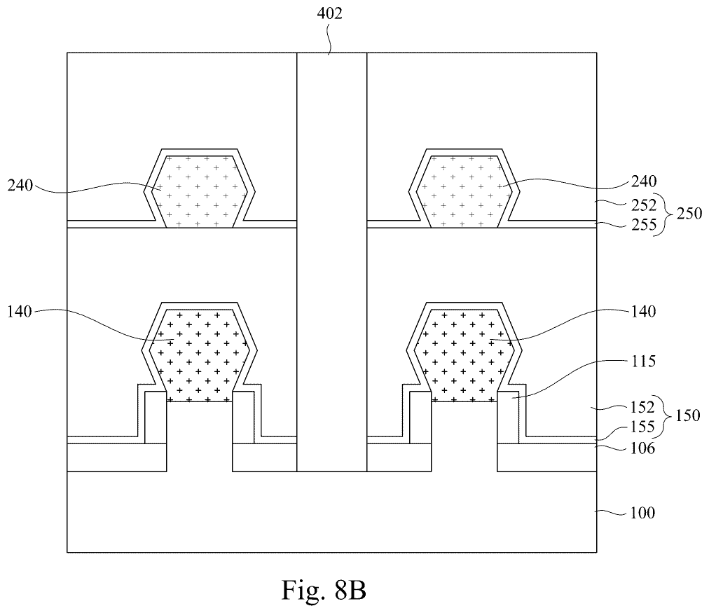

Reference is made to FIGS. 8A and 8B. A dielectric structure 500 is formed. As shown in FIG. 8B, the dielectric structure 500 may also cut through the isolation structures 150 and 250. In some embodiments, the dielectric structure 500 may extend through the isolation structures 106 and in contact with the substrate 100. In some embodiments, the dielectric structure 500 may also be referred to as a cut-metal-gate (CMG) isolation structure.

The dielectric structure 500 may be made of nitride (e.g., silicon nitride), oxide (e.g., silicon oxide), combinations thereof, or suitable dielectric material. The dielectric structure 500 may be formed by, for example, etching the first metal gate structure 170, the second metal gate structure 270, and the isolation structures 150 and 250 to form an opening, depositing a dielectric material in the opening, and then performing a planarization process (such as CMP) to remove excess materials of the dielectric material.

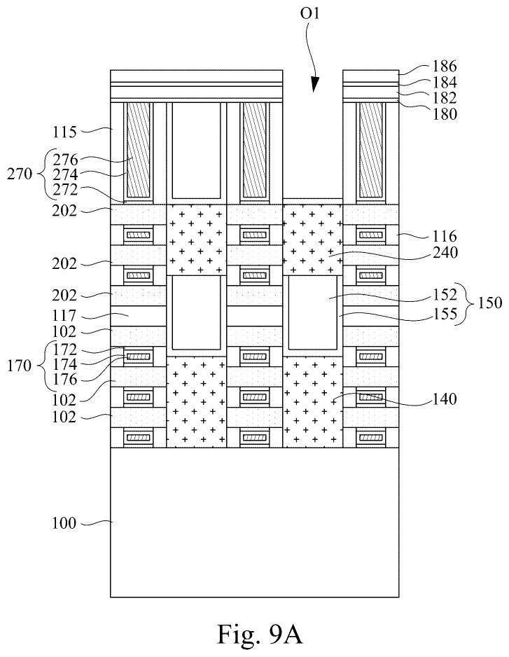

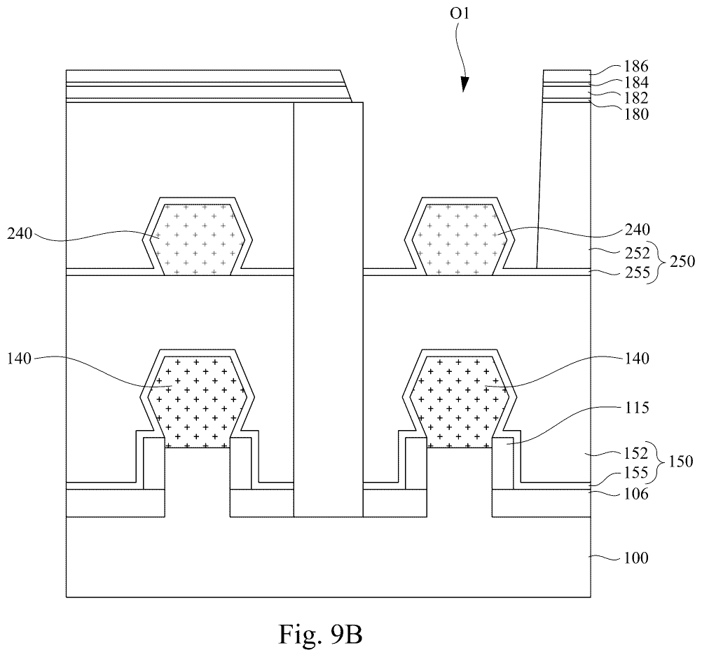

Reference is made to FIGS. 9A and 9B. An etch stop layer (ESL) 180 is formed over the isolation structures 250 and the second metal gate structures 270, an interlayer dielectric (ILD) layer 182 is formed over the ESL 180, an ESL 184 is formed over the ILD layer 182, and an ILD layer 186 is formed over the ESL 184. The materials of the ESLs 180 and 184 and the ILD layers 182 and 186 may be similar to the materials of the CESL 155 and the ILD layer 152, respectively. For example, the ESLs 180 and 184 may be nitride) and the ILD layers 182 and 186 may be oxide. The ESLs 180 and 184 and the ILD layers 182 and 186 can be formed using, for example, CVD, ALD or other suitable techniques.

An opening O1 is formed in the ILD layer 186, the ESL 184, the ILD layer 182, and the ESL 180. The opening O1 can be formed by suitable lithography process and etching process. The ILD layer 252 of the isolation structure 250 is then etched through the opening O1, so as to expose the CESL 255 of the isolation structure 250. In some embodiments, the etchant of the etching process can be selected to have a higher etch rate to the material of the ILD layer 252 than to the material of the CESL 255, such that the CESL 255 can act as an etch stop layer for etching the ILD layer 252.

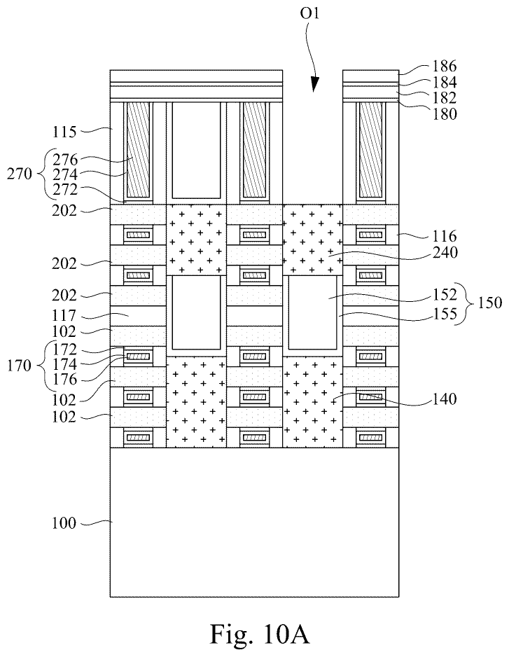

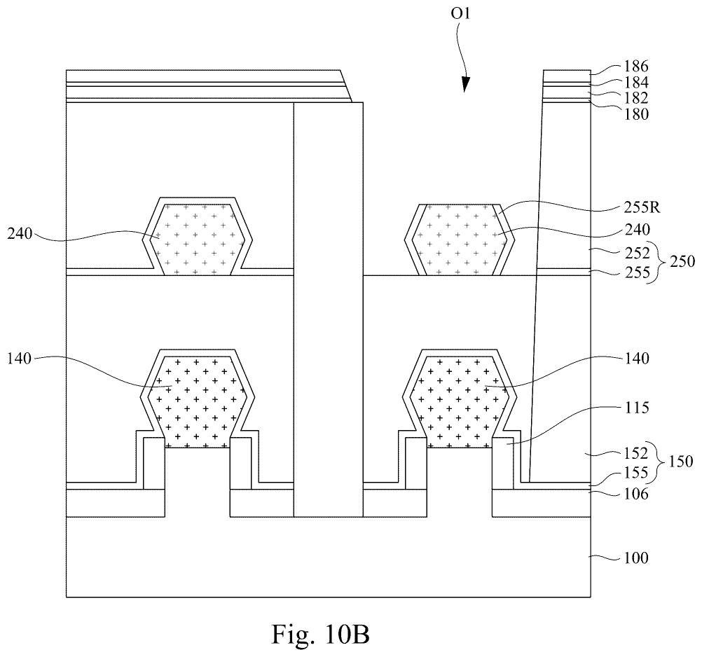

Reference is made to FIGS. 10A and 10B. An etching process is performed to remove horizontal portions of the CESL 255. In greater detail, as shown in FIG. 10B, the horizontal portions of the CESL 255 over the top surface of the source/drain epitaxy structure 240 and over the top surface of the ILD layer 152 are removed, while the substantially vertical portions of the CESL 255 remains on opposite sidewalls of the source/drain epitaxy structure 240 once the etching process is complete. As a result, top surface of the source/drain epitaxy structure 240 and portions of top surface of the ILD layer 152 are exposed. In some embodiments, the etching process is a directional dry etching process, such as a plasma etching. The remaining portions of the CESL 255 on opposite sidewalls of the source/drain epitaxy structure 240 are referred to as CESL 255R, or can also be referred to as spacers 255R.

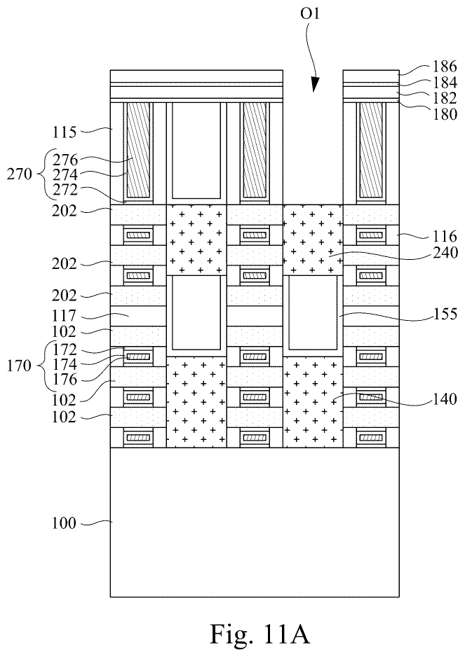

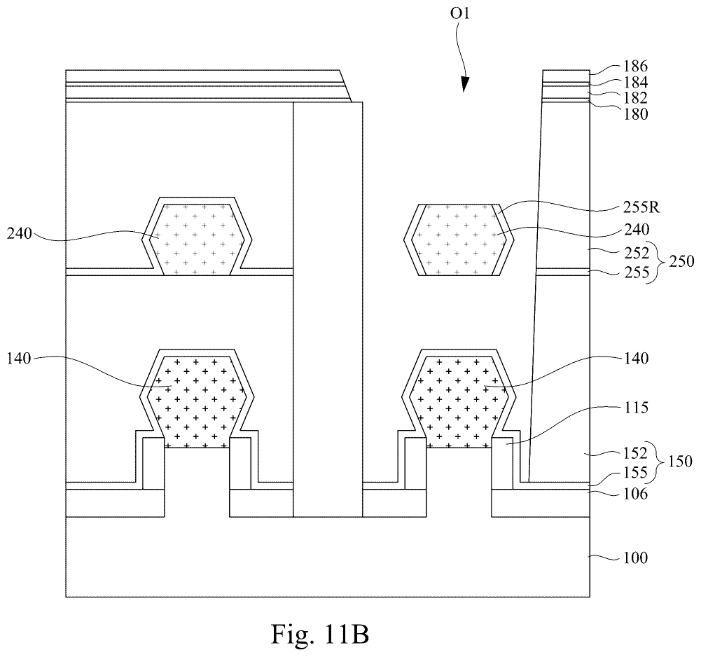

Reference is made to FIGS. 11A and 11B. Portions of the ILD layer 152 of the isolation structure 150 is then etched through the opening O1, so as to expose the CESL 155 of the isolation structure 150. In some embodiments, the etchant of the etching process can be selected to have a higher etch rate to the material of the ILD layer 152 than to the material of the CESL 155, such that the CESL 155 can act as an etch stop layer for etching the ILD layer 152. In some embodiments, once the portions of the ILD layer 152 of the isolation structure 150 is removed, bottom surface of the source/drain epitaxy structure 140 is exposed to the opening O1.

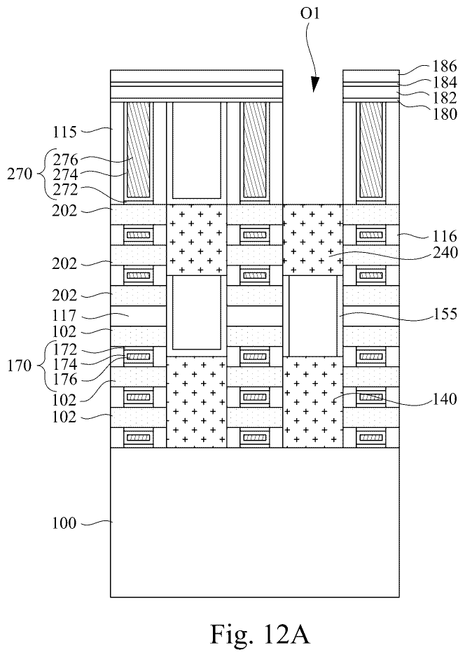

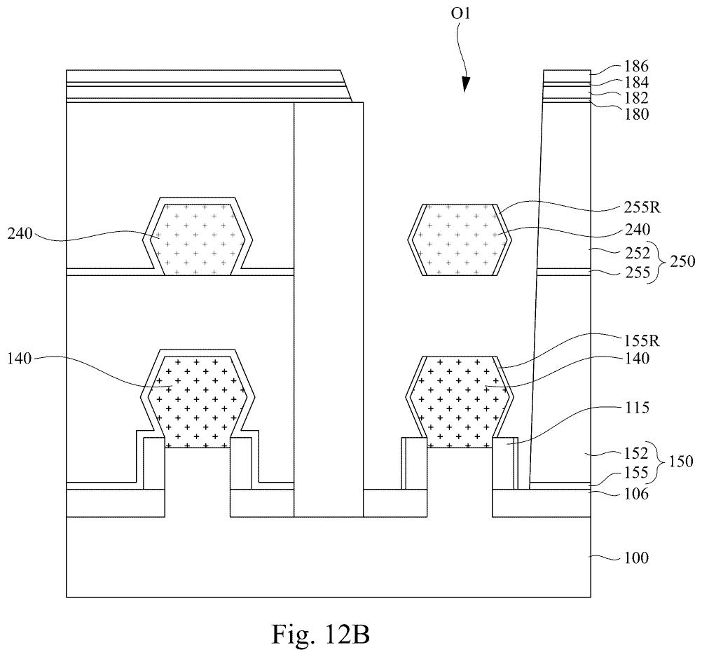

Reference is made to FIGS. 12A and 12B. An etching process is performed to remove horizontal portions of the CESL 155. In greater detail, as shown in FIG. 12B, the horizontal portions of the CESL 155 over the top surface of the source/drain epitaxy structure 140, over the top surfaces of the spacers 115, and over the top surfaces of the isolation structures 106 are removed, while the substantially vertical portions of the CESL 155 remains on opposite sidewalls of the source/drain epitaxy structure 140 once the etching process is complete. As a result, top surface of the source/drain epitaxy structure 140 and portions of top surfaces of the spacers 115 and the isolation structures 106 are exposed. In some embodiments, the etching process is a directional dry etching process, such as a plasma etching. The remaining portions of the CESL 155 on opposite sidewalls of the source/drain epitaxy structure 140 are referred to as CESL 155R, or can also be referred to as spacers 155R. In some embodiments, the spacers 155R and 255R may be made of a same material. In some embodiments, thickness the spacers 255R on opposite sidewalls of the source/drain epitaxy structure 240 may also be reduced during the etching process of FIGS. 12A and 12B.

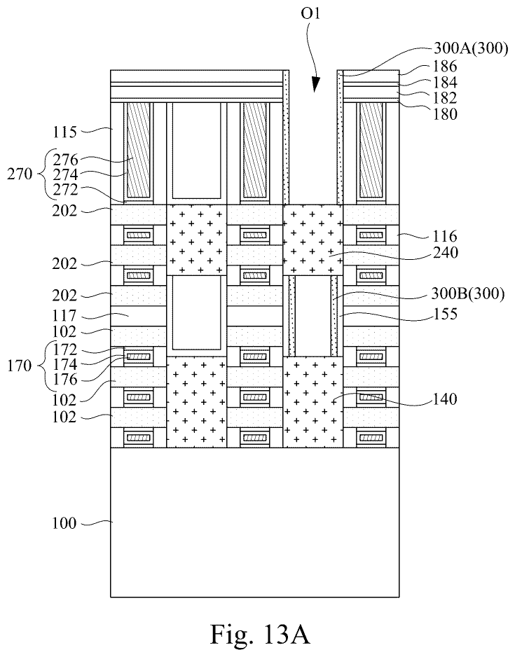

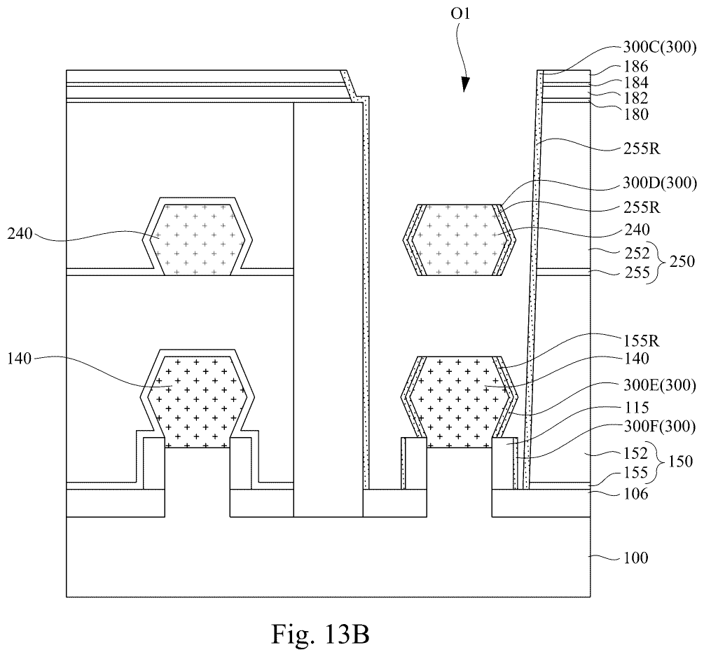

Reference is made to FIGS. 13A and 13B. A spacer layer 300 is formed blanket over the structure shown in FIGS. 12A and 12B, and an etching process is performed to remove horizontal portions of the spacer layer 300, while leaving substantially vertical portions of the spacer layer 300 remaining on the structure. In some embodiments, the etching process is a directional dry etching process, such as a plasma etching.

As shown in the cross-sectional view of FIG. 13A, portions 300A of the spacer layer 300 may extend along the sidewalls of the ILD layer 186, the ESL 184, the ILD layer 182, the ESL 180, and the spacer 115. Portions 300B of the spacer layer 300 may extend along the sidewalls of the CESL 155 of the isolation structure 150.

As shown in the cross-sectional view of FIG. 13B, portions 300C of the spacer layer 300 may extend along the sidewalls of the ILD layer 186, the ESL 184, the ILD layer 182, the ESL 180, the ILD layer 252, the CESL 255, the ILD layer 152, the CESL 155, and may be in contact with top surfaces of the isolation structures 106. Portions 300D of the spacer layer 300 may be in contact with the spacers 255R, and may be disposed on opposite sides of the source/drain epitaxy structure 240, in which the portions 300D of the spacer layer 300 may be spaced apart from the source/drain epitaxy structure 240 through the spacers 255R. Portions 300E of the spacer layer 300 may be in contact with the spacers 155R, and may be disposed on opposite sides of the source/drain epitaxy structure 140, in which the portions 300E of the spacer layer 300 may be spaced apart from the source/drain epitaxy structure 140 through the spacers 155R. Portions 300F of the spacer layer 300 may extend along sidewalls of the spacers 115. In some embodiments, the portions 300A to 300F of the spacer layer 300 can also be referred to as spacers 300A to 300F.

With respect to the source/drain epitaxy structure 140, it can be seen that spacers 155R are disposed on opposite sides of the source/drain epitaxy structure 140, and the spacers 300F are disposed on sidewalls of the spacers 155R. That is, the spacers 155R and 300F can be collectively referred to as dual-layer spacer structures (or multi-layer spacer structure) on opposite sidewalls of the source/drain epitaxy structure 140. Similarly, it can be seen that spacers 255R are disposed on opposite sides of the source/drain epitaxy structure 240, and the spacers 300E are disposed on sidewalls of the spacers 255R. That is, the spacers 255R and 300E can be collectively referred to as dual-layer spacer structures (or multi-layer spacer structure) on opposite sidewalls of the source/drain epitaxy structure 240.

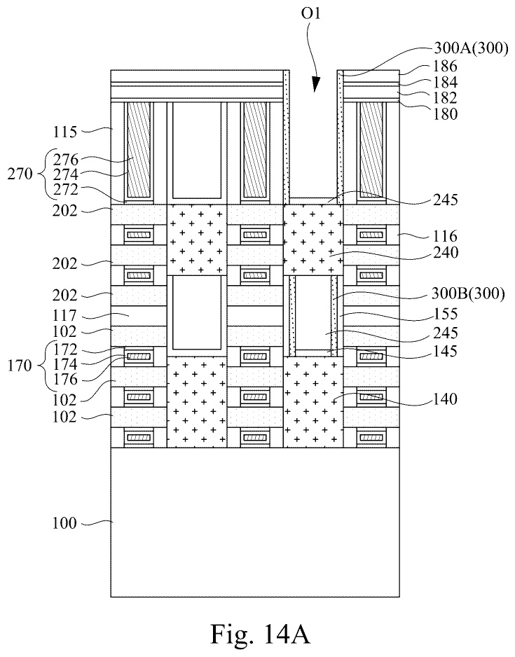

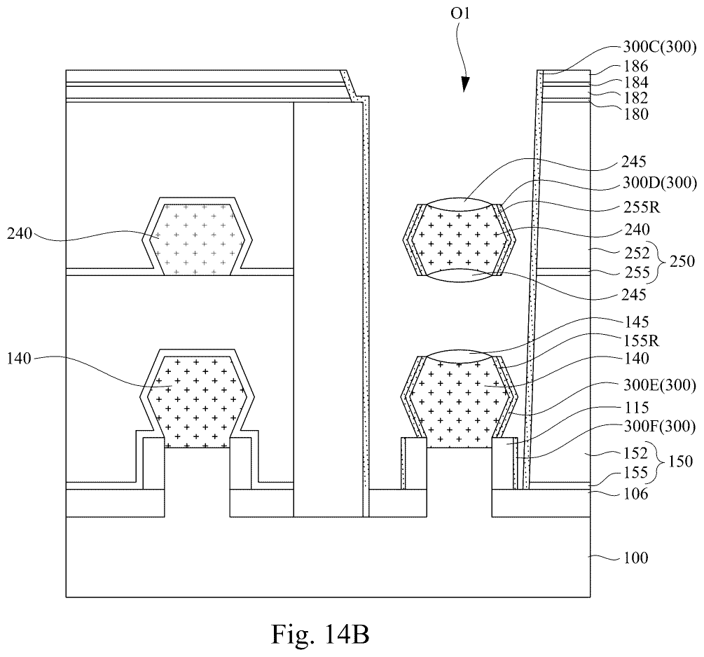

Reference is made to FIGS. 14A and 14B. Silicide layer 145 is formed on the exposed top surface of the source/drain epitaxy structure 140, and silicide layers 245 are formed on the exposed top surface and the exposed bottom surface of the source/drain epitaxy structure 240. In some embodiments, the silicide layers 145 and 245 can be formed in a selective manner. For example, to form the silicide layers 145 and 245, a metal-containing precursor is supplied to the opening O1, and an anneal process is performed to bring about silicidation reaction between the metal source and the exposed surfaces of the source/drain epitaxy structures 140 and 240. In some embodiments, the silicide layers 145 and 245 may include different metal silicides, depending on the materials of the source/drain epitaxy structures 140 and 240. For example, if the source/drain epitaxy structure 140 is silicon germanium (SiGe) for a P-type device, the silicide layer 145 may be a MSiGe layer, where M is metal element. On the other hand, if the source/drain epitaxy structure 240 is silicon (Si) for an N-type device, the silicide layers 245 may be a MSi layer, where M is metal element. In some embodiments, the metal M may be titanium (Ti), tantalum (Ta), nickel (Ni), cobalt (Co), tungsten (W), or the like. In some embodiments, the silicide layers 145 and 245 may be TiSiGe and TiSi, respectively. In some embodiments, a pre-clean process may be performed to the exposed surfaces of the source/drain epitaxy structures 140 and 240 prior to forming the silicide layers 145 and 245.

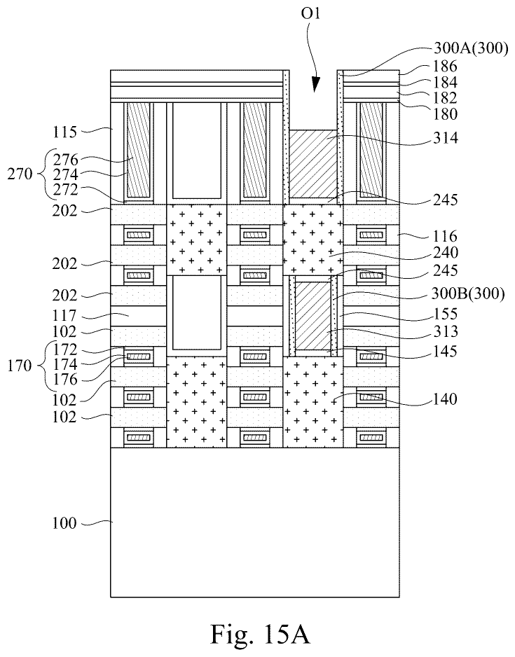

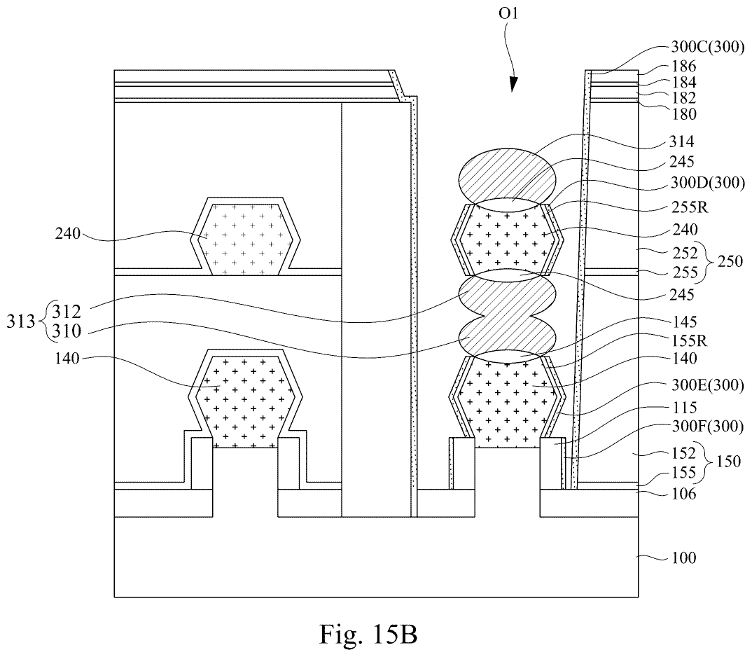

Reference is made to FIGS. 15A and 15B. A deposition process is performed to selectively deposit metal material from the silicide layers 145 and 245. For example, the deposition process may include an electroplating process. The metal elements of the silicide layers 145 and 245 can act as seed layers for the metal material. As a result, a metal plug 310 is grown from the exposed surface of the silicide layer 145, a metal plug 312 is grown from the exposed bottom surface of the silicide layer 245, and a metal plug 314 is grown from the exposed top surface of the silicide layer 245. In some embodiments, the metal plug 310 is grown upwardly from the silicide layer 145, and the metal plug 312 is grown downwardly from the bottom silicide layer 245, and the deposition process is performed until the metal plugs 310 and 312 are merged with each other to form a merged metal plug 313. As a result, the source/drain epitaxy structures 140 and 240 can be electrically connected with each other through the silicide layers 145 and 245, and the metal plug 313. In some embodiments, the metal plugs 310, 312, and 314 may include a same metal, such as tungsten (W), molybdenum (Mo), ruthenium (Ru), Iridium (Ir), or other suitable metal.

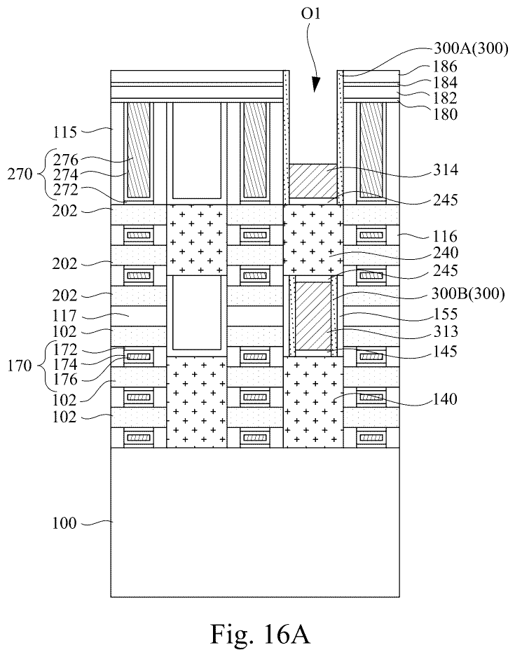

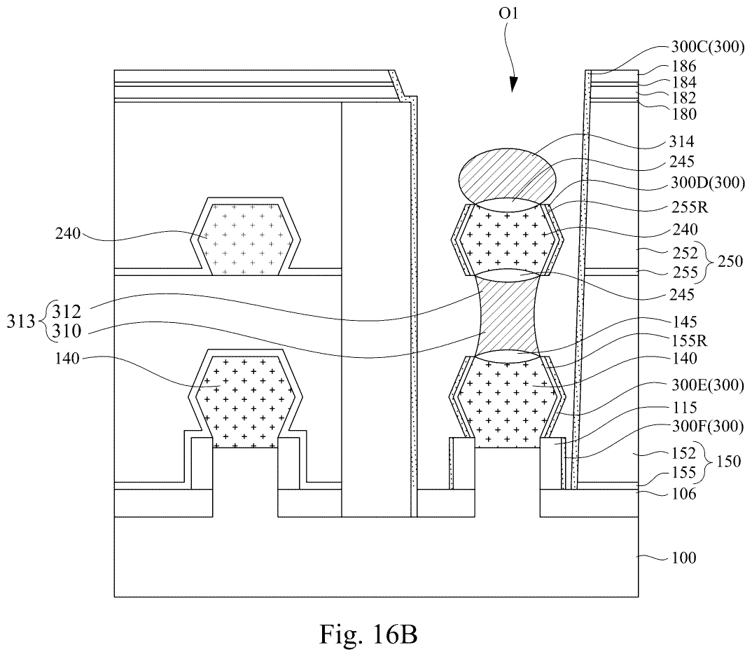

Reference is made to FIGS. 16A and 16B. An etching process is performed to shrink the metal plug 313. As shown in FIG. 16B, the lateral width of the metal plug 313 may be reduced as a result of the etching process. In some embodiments, the metal plug 314 may also be shrunk during the etching process. For example, the vertical thickness of the metal plug 314 may be reduced as a result of the etching process. In some embodiments, the etching process is a directional dry etching process, such as a plasma etching.

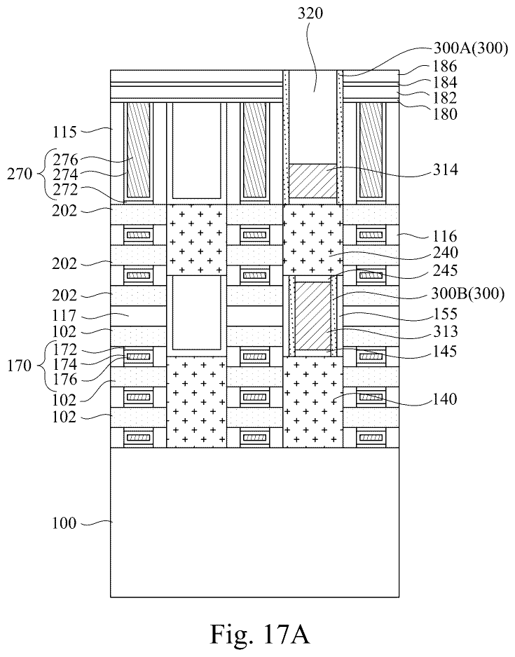

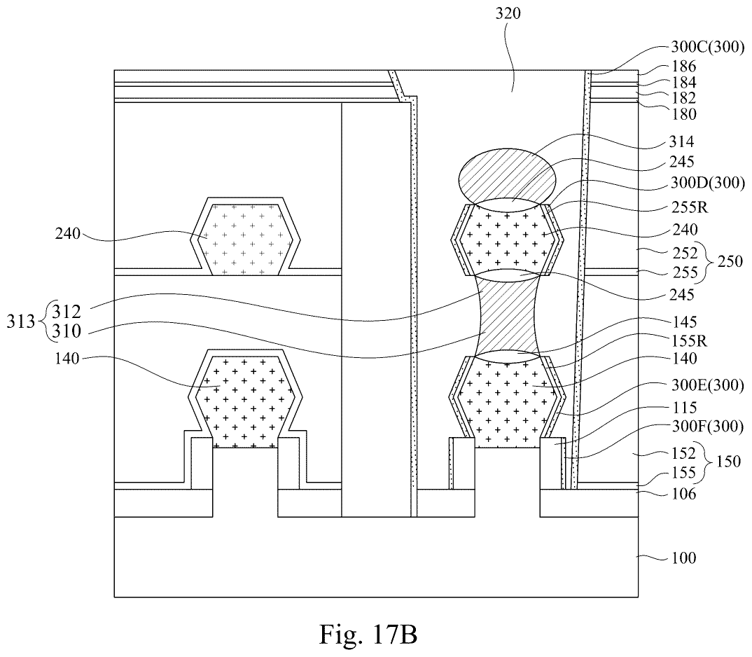

Reference is made to FIGS. 17A and 17B. An interlayer dielectric (ILD) layer 320 is deposited in the opening O1, and a planarization process (e.g., CMP) is performed to remove excess material of the interlayer dielectric layer 320 until the ILD layer 186 is exposed. The material of the ILD layer 320 may be similar to the ILD layer 152, such as oxide. The ILD layer 320 may cover the metal plugs 313 and 314, and may also cover the spacers 300A to 300F.

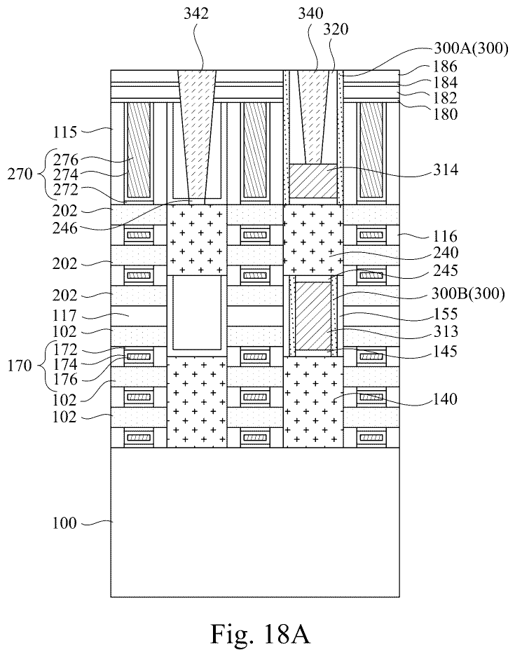

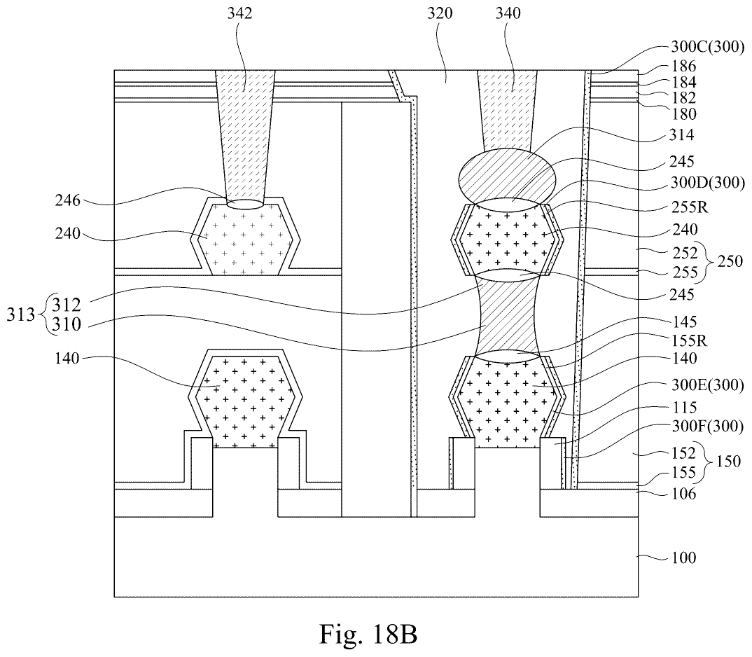

Reference is made to FIGS. 18A and 18B. Metal vias 340 and 342 are formed. In greater detail, the metal via 340 is formed in the ILD layer 320, and is in contact with top surface of the metal plug 314. On the other hand, the metal via 342 is formed in the ILD layer 186, the ESL 184, the ILD layer 182, the ESL 180, and the ILD layer 152, and is electrically connected to another one of the source/drain epitaxy structure 240. In some embodiments, a silicide layer 246 may be formed on the another one of the source/drain epitaxy structure 240 prior to forming the metal via 342. In some embodiments, bottom surface of the metal via 340 may be higher than bottom surface of the metal via 342. In some embodiments, the metal vias 340 and 342 may include suitable material, such as tungsten (W), molybdenum (Mo), ruthenium (Ru), Iridium (Ir), or other suitable metal.

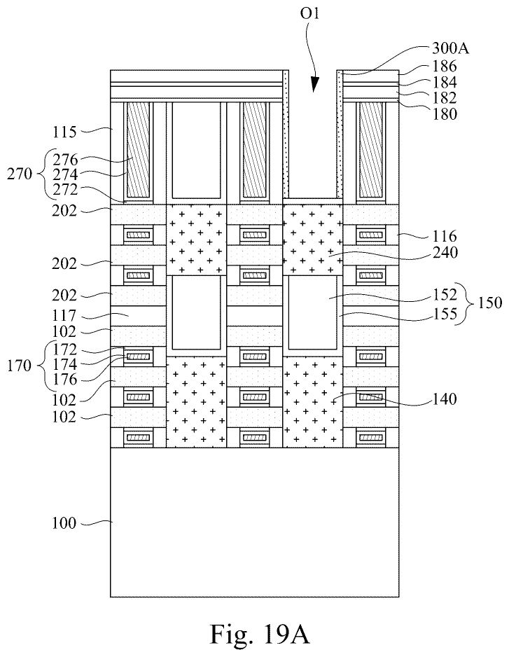

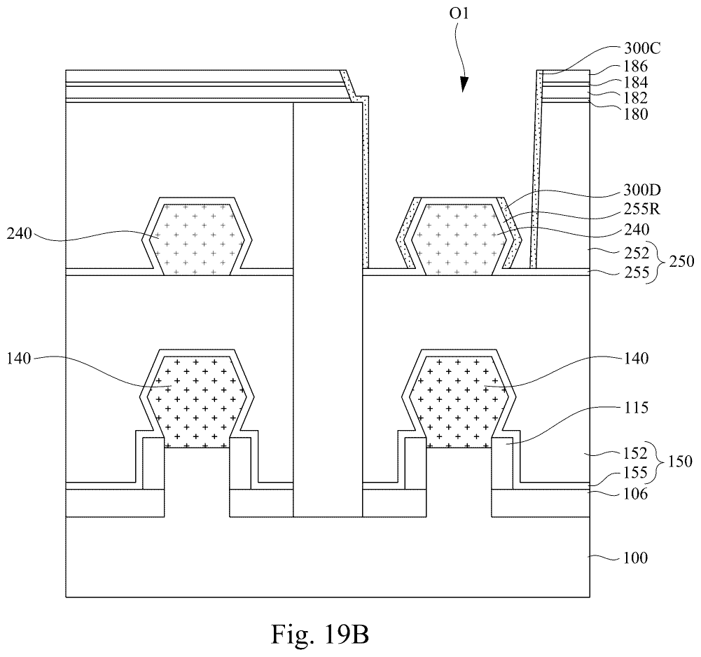

FIGS. 19A to 24B illustrate a method in various stages of forming a semiconductor device in accordance with some embodiments of the present disclosure. It is noted that some elements of FIGS. 19A to 24B have been discussed above with respect to FIGS. 2A to 18B, such elements are labeled the same and relevant details may not be repeated for brevity.

Reference is made to FIGS. 19A and 19B. A spacer layer 300 is formed blanket over the structure shown in FIGS. 9A and 9B, and an etching process is performed to remove horizontal portions of the spacer layer 300, while leaving substantially vertical portions of the spacer layer 300 remaining on the structure. In some embodiments, the etching process is a directional dry etching process, such as a plasma etching.

As shown in the cross-sectional view of FIG. 19A, portions 300A of the spacer layer 300 may extend along the sidewalls of the ILD layer 186, the ESL 184, the ILD layer 182, the ESL 180, and the spacer 115. Portions 300B of the spacer layer 300 may extend along the sidewalls of the CESL 155 of the isolation structure 150.

As shown in the cross-sectional view of FIG. 19B, portions 300C of the spacer layer 300 may extend along the sidewalls of the ILD layer 186, the ESL 184, the ILD layer 182, the ESL 180, the ILD layer 252, the CESL 255, the ILD layer 152, the CESL 155, and may be in contact with top surfaces of the isolation structures 106. Portions 300D of the spacer layer 300 may be in contact with the CESL 255, and may be disposed on opposite sides of the source/drain epitaxy structure 240, in which the portions 300D of the spacer layer 300 may be spaced apart from the source/drain epitaxy structure 240 through the CESL 255. In some embodiments, it can be seen that portions of the CESL 255 that are over top surface of the source/drain epitaxy structure 240 and over top surface of the ILD layer 152 may be exposed.

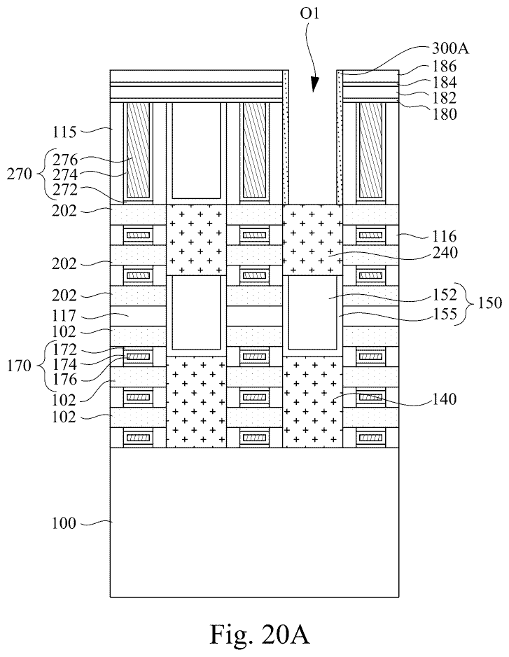

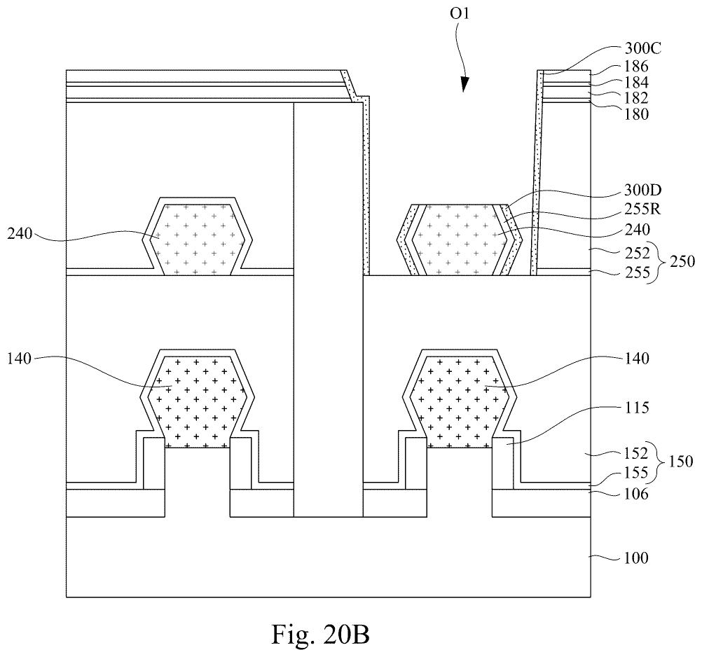

Reference is made to FIGS. 20A and 20B. An etching process is performed to remove exposed horizontal portions of the CESL 255. In greater detail, as shown in FIG. 20B, the exposed horizontal portions of the CESL 255 over the top surface of the source/drain epitaxy structure 240 and over the top surface of the ILD layer 152 are removed, while the substantially vertical portions of the CESL 255 are protected by the spacers 300D, and may remain on opposite sidewalls of the source/drain epitaxy structure 240 once the etching process is complete. As a result, top surface of the source/drain epitaxy structure 240 and portions of top surface of the ILD layer 152 are exposed. In some embodiments, the etching process is a directional dry etching process, such as a plasma etching. The remaining portions of the CESL 255 on opposite sidewalls of the source/drain epitaxy structure 240 are referred to as CESL 255R, or can also be referred to as spacers 255R.

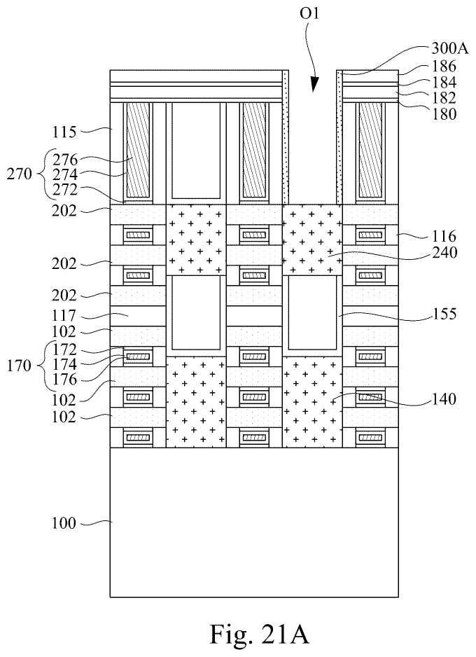

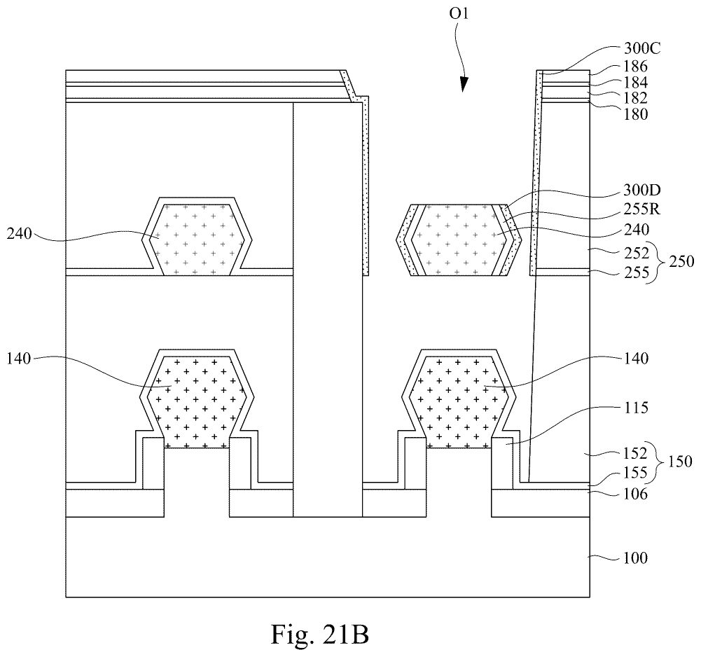

Reference is made to FIGS. 21A and 21B. Portions of the ILD layer 152 of the isolation structure 150 is then etched through the opening O1, so as to expose the CESL 155 of the isolation structure 150. In some embodiments, the etchant of the etching process can be selected to have a higher etch rate to the material of the ILD layer 152 than to the material of the CESL 155, such that the CESL 155 can act as an etch stop layer for etching the ILD layer 152. In some embodiments, once the portions of the ILD layer 152 of the isolation structure 150 is removed, bottom surface of the source/drain epitaxy structure 140 is exposed to the opening O1.

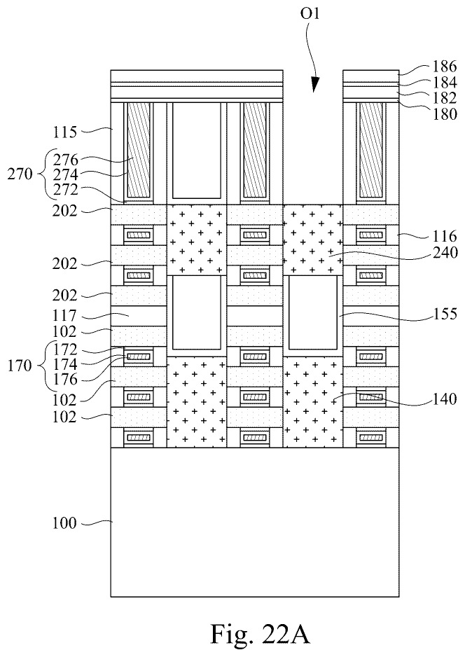

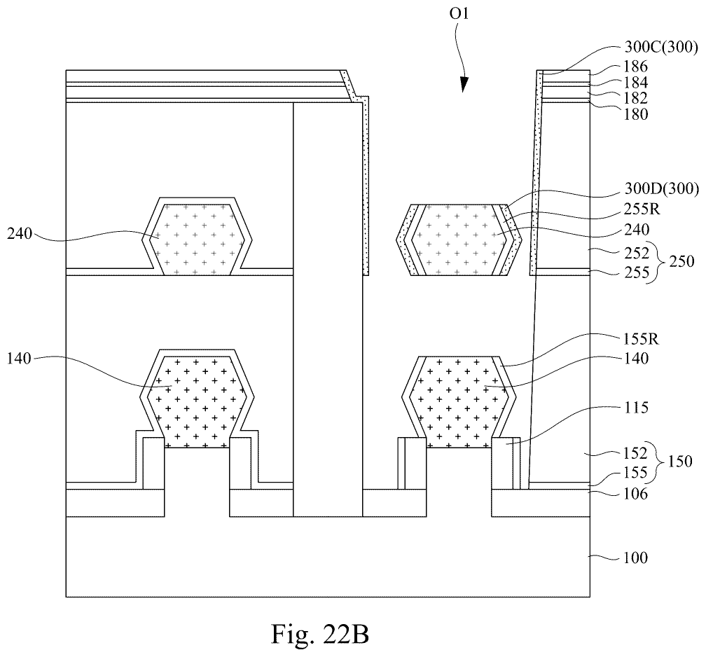

Reference is made to FIGS. 22A and 22B. An etching process is performed to remove horizontal portions of the CESL 155. In greater detail, as shown in FIG. 22B, the horizontal portions of the CESL 155 over the top surface of the source/drain epitaxy structure 140, over the top surfaces of the spacers 115, and over the top surfaces of the isolation structures 106 are removed, while the substantially vertical portions of the CESL 155 remains on opposite sidewalls of the source/drain epitaxy structure 140 once the etching process is complete. As a result, top surface of the source/drain epitaxy structure 140 and portions of top surfaces of the spacers 115 and the isolation structures 106 are exposed. In some embodiments, the etching process is a directional dry etching process, such as a plasma etching. The remaining portions of the CESL 155 on opposite sidewalls of the source/drain epitaxy structure 140 are referred to as CESL 155R, or can also be referred to as spacers 155R. In some embodiments, the spacers 155R and 255R may be made of a same material.

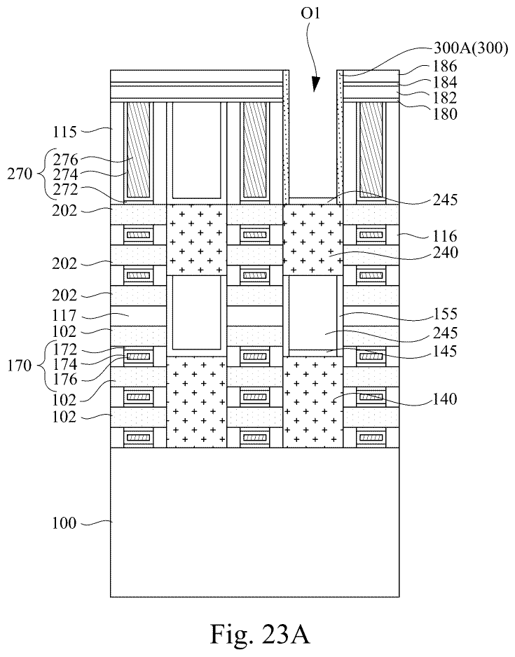

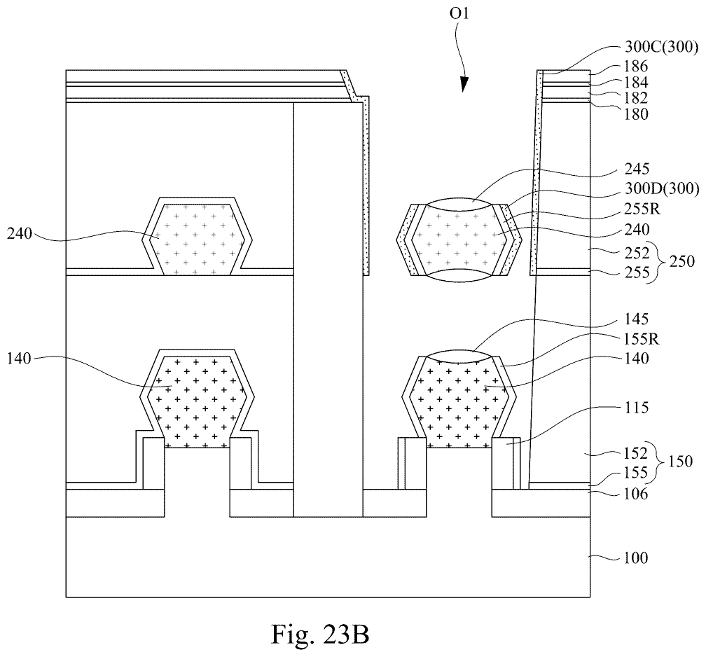

Reference is made to FIGS. 23A and 23B. Silicide layer 145 is formed on the exposed top surface of the source/drain epitaxy structure 140, and silicide layers 245 are formed on the exposed top surface and the exposed bottom surface of the source/drain epitaxy structure 240. In some embodiments, the silicide layers 145 and 245 can be formed in a selective manner. For example, to form the silicide layers 145 and 245, a metal-containing precursor is supplied to the opening O1, and an anneal process is performed to bring about silicidation reaction between the metal source and the exposed surfaces of the source/drain epitaxy structures 140 and 240. In some embodiments, the silicide layers 145 and 245 may include different metal silicides, depending on the materials of the source/drain epitaxy structures 140 and 240. For example, if the source/drain epitaxy structure 140 is silicon germanium (SiGe) for a P-type device, the silicide layer 145 may be a MSiGe layer, where M is metal element. On the other hand, if the source/drain epitaxy structure 240 is silicon (Si) for an N-type device, the silicide layers 245 may be a MSi layer, where M is metal element. In some embodiments, the metal M may be titanium (Ti), tantalum (Ta), nickel (Ni), cobalt (Co), tungsten (W), or the like. In some embodiments, the silicide layers 145 and 245 may be TiSiGe and TiSi, respectively. In some embodiments, a pre-clean process may be performed to the exposed surfaces of the source/drain epitaxy structures 140 and 240 prior to forming the silicide layers 145 and 245.

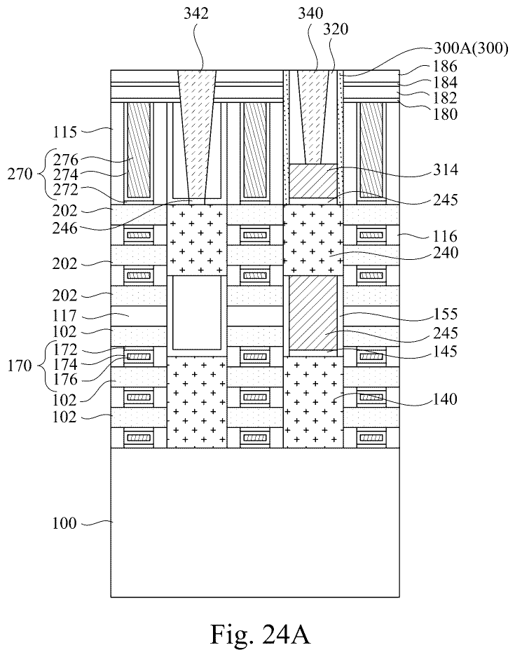

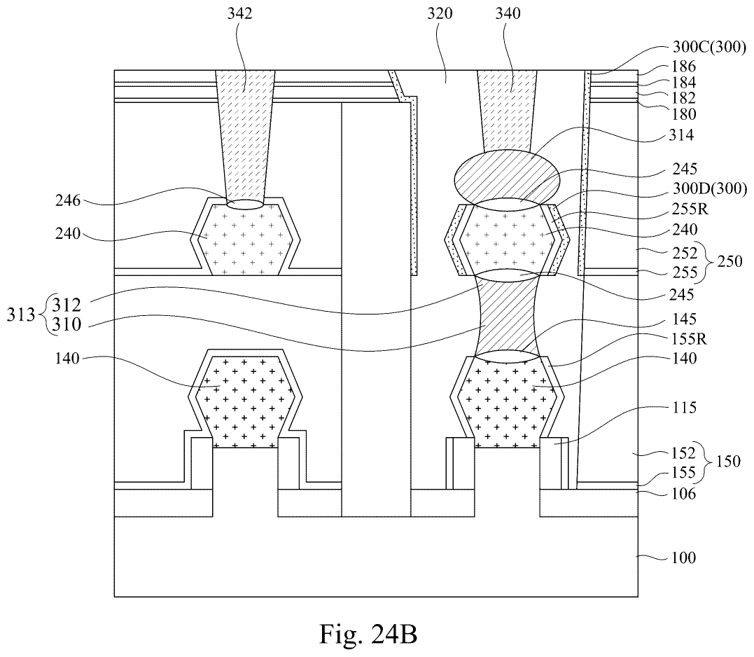

Reference is made to FIGS. 24A and 24B. The structure shown FIGS. 23A and 23B may undergo the processes as discussed in FIGS. 15A to 18B, and the resulting structure is shown in FIGS. 24A and 24B. The structure of embodiments shown in FIGS. 24A and 24B is different from the structure of embodiments shown in FIGS. 18A and 18B, in that the spacer layer 300 is above the ILD layer 152, and thus the spacer layer 300 does not include portions lining the spacers 155R and the isolation structure 150. Accordingly, the ILD layer 320 may be in contact with the isolation structure 150, the isolation structure 106, and the spacers 155R. In some embodiments, because there is no spacer layer 300 formed on the spacers 155R, the spacers 155R can be referred to as a single-layer spacer structure on opposite sidewalls of the source/drain epitaxy structure 140, in which the single-layer spacer is free of the material of the spacer layer 300. In contrast, the spacers 255R and 300D can be referred to as dual-layer spacer structures on opposite sidewalls of the source/drain epitaxy structure 240.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a method for forming a contact between a top source/drain epitaxy structure and a bottom source/drain epitaxy structure without etching through the top source/drain epitaxy structure. Moreover, the contact can be formed in a self-aligned manner. With such configuration, the contact region between the source/drain epitaxy structure and the silicide layer can be enlarged, and the resistance of the device can be reduced. As a result, the device performance is improved.

In some embodiments of the present disclosure, a semiconductor device includes a substrate. A bottom device is over the substrate comprises a bottom source/drain structure. A top device is vertically above the bottom device and comprises a top source/drain structure. A first metal plug is vertically between the bottom source/drain structure and the top source/drain structure, in which a top surface of the first metal plug is lower than a top surface of the top source/drain structure.

In some embodiments, the semiconductor device further includes a first silicide layer between the top surface of the first metal plug and a bottom surface of the top source/drain structure, and a second silicide layer between a bottom surface of the first metal plug and a top surface of the bottom source/drain structure.

In some embodiments, the first silicide layer and the second silicide layer are made of different metal silicides.

In some embodiments, the semiconductor device further includes a first silicide layer in contact with a bottom surface of the top source/drain structure, and a second silicide layer in contact with a top surface of the top source/drain structure.

In some embodiments, the semiconductor device further includes a second metal plug in contact with a top surface of the second silicide layer, wherein the first metal plug and the second metal plug are made of a same metal.

In some embodiments, the semiconductor device further includes an interlayer dielectric layer surrounding the bottom source/drain structure, the top source/drain structure, and the first metal plug.

In some embodiments, the semiconductor device further includes a first spacer structure on a sidewall of the bottom source/drain structure, and a second spacer structure on a sidewall of the top source/drain structure.

In some embodiments, the first spacer structure and the second spacer structure both are a dual-layer spacer structure.

In some embodiments, the first spacer structure is a single-layer spacer structure and the second spacer structure is a dual-layer spacer structure.

In some embodiments of the present disclosure, a semiconductor device includes a substrate. A bottom device is over the substrate comprises a bottom source/drain structure. A top device is vertically above the bottom device and comprises a top source/drain structure. A first spacer structure is on a sidewall of the bottom source/drain structure. A second spacer structure is on a sidewall of the top source/drain structure. An interlayer dielectric layer surrounds the bottom source/drain structure and the top source/drain structure, and in contact with the first and second spacer structures.

In some embodiments, the semiconductor device further includes a first silicide layer in contact with a top surface of the bottom source/drain structure, a second silicide layer in contact with a bottom surface of the top source/drain structure, and a first metal plug between the first silicide layer and the second silicide layer.

In some embodiments, the semiconductor device further includes a third silicide layer in contact with a top surface of the top source/drain structure, a second metal plug in the interlayer dielectric layer and over the third silicide layer, and a metal via in the interlayer dielectric layer and over the second metal plug.

In some embodiments, the second spacer structure comprises a first spacer along the sidewall of the top source/drain structure and a second spacer on a sidewall of the first spacer.

In some embodiments, the first spacer structure comprises a first spacer along the sidewall of the bottom source/drain structure and a second spacer on a sidewall of the first spacer.

In some embodiments, the first spacer structure is free of a material of the second spacer.

In some embodiments of the present disclosure, a method includes forming a bottom device over the substrate comprising a bottom source/drain structure, wherein the bottom source/drain structure is surrounded by a first isolation structure; forming a top device vertically above the bottom device and comprising a top source/drain structure, wherein the top source/drain structure is surrounded by a second isolation structure; removing portions of the first isolation structure and the second isolation structure to expose a top surface of the bottom source/drain structure and a bottom surface of the top source/drain structure; and forming a metal plug vertically between the top surface of the bottom source/drain structure and the bottom surface of the top source/drain structure.

In some embodiments, the method further includes prior to forming the metal plug, forming a first silicide layer on the top surface of the bottom source/drain structure and a second silicide layer on the bottom surface of the top source/drain structure.

In some embodiments, forming the metal plug comprises selectively depositing a first metal from the first silicide layer and a second metal from the second silicide layer until the first metal and the second metal are merged with each other.

In some embodiments, the method further includes performing an etching process to shrink the metal plug.

In some embodiments, the method further includes forming spacers on opposite sidewalls of the top source/drain structure prior to forming the metal plug.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a bottom device over the substrate comprising a bottom source/drain structure;
a top device vertically above the bottom device and comprising a top source/drain structure; and
a first metal plug vertically between the bottom source/drain structure and the top source/drain structure, wherein a top surface of the first metal plug is lower than a top surface of the top source/drain structure.

2. The semiconductor device of claim 1, further comprising:
a first silicide layer between the top surface of the first metal plug and a bottom surface of the top source/drain structure; and
a second silicide layer between a bottom surface of the first metal plug and a top surface of the bottom source/drain structure.

3. The semiconductor device of claim 2, wherein the first silicide layer and the second silicide layer are made of different metal silicides.

4. The semiconductor device of claim 1, further comprising:
a first silicide layer in contact with a bottom surface of the top source/drain structure; and
a second silicide layer in contact with a top surface of the top source/drain structure.

5. The semiconductor device of claim 4, further comprising a second metal plug in contact with a top surface of the second silicide layer, wherein the first metal plug and the second metal plug are made of a same metal.

6. The semiconductor device of claim 1, further comprising an interlayer dielectric layer surrounding the bottom source/drain structure, the top source/drain structure, and the first metal plug.

7. The semiconductor device of claim 1, further comprising:
a first spacer structure on a sidewall of the bottom source/drain structure; and
a second spacer structure on a sidewall of the top source/drain structure.

8. The semiconductor device of claim 7, wherein the first spacer structure and the second spacer structure both are a dual-layer spacer structure.

9. The semiconductor device of claim 7, wherein the first spacer structure is a single-layer spacer structure and the second spacer structure is a dual-layer spacer structure.

10. A semiconductor device, comprising:
a substrate;
a bottom device over the substrate comprising a bottom source/drain structure;
a top device vertically above the bottom device and comprising a top source/drain structure;
a first spacer structure on a sidewall of the bottom source/drain structure;
a second spacer structure on a sidewall of the top source/drain structure; and
an interlayer dielectric layer surrounding the bottom source/drain structure and the top source/drain structure, and in contact with the first and second spacer structures.

11. The semiconductor device of claim 10, further comprising:
a first silicide layer in contact with a top surface of the bottom source/drain structure;
a second silicide layer in contact with a bottom surface of the top source/drain structure; and
a first metal plug between the first silicide layer and the second silicide layer.

12. The semiconductor device of claim 11, further comprising:
a third silicide layer in contact with a top surface of the top source/drain structure;
a second metal plug in the interlayer dielectric layer and over the third silicide layer; and
a metal via in the interlayer dielectric layer and over the second metal plug.

13. The semiconductor device of claim 10, wherein the second spacer structure comprises a first spacer along the sidewall of the top source/drain structure and a second spacer on a sidewall of the first spacer.

14. The semiconductor device of claim 13, wherein the first spacer structure comprises a first spacer along the sidewall of the bottom source/drain structure and a second spacer on a sidewall of the first spacer.

15. The semiconductor device of claim 13, wherein the first spacer structure is free of a material of the second spacer.

16. A method, comprising:
forming a bottom device over the substrate comprising a bottom source/drain structure, wherein the bottom source/drain structure is surrounded by a first isolation structure;
forming a top device vertically above the bottom device and comprising a top source/drain structure, wherein the top source/drain structure is surrounded by a second isolation structure;
removing portions of the first isolation structure and the second isolation structure to expose a top surface of the bottom source/drain structure and a bottom surface of the top source/drain structure; and
forming a metal plug vertically between the top surface of the bottom source/drain structure and the bottom surface of the top source/drain structure.

17. The method of claim 16, further comprising prior to forming the metal plug, forming a first silicide layer on the top surface of the bottom source/drain structure and a second silicide layer on the bottom surface of the top source/drain structure.

18. The method of claim 17, wherein forming the metal plug comprises selectively depositing a first metal from the first silicide layer and a second metal from the second silicide layer until the first metal and the second metal are merged with each other.

19. The method of claim 16, further comprising performing an etching process to shrink the metal plug.

20. The method of claim 16, further comprising forming spacers on opposite sidewalls of the top source/drain structure prior to forming the metal plug.
